(19) United States
(12) Patent Application Publication
(10) Pub. No.: US 2020/0006305 A1
(43) Pub. Date: Jan. 2, 2020

(54) INTEGRATED HETEROGENOUS POWER MANAGEMENT CIRCUITRIES

(71) Applicant: Intel Corporation, Santa Clara, CA (US)

(72) Inventors: William J. Lambert, Chandler, AZ (US); Krishna Bharath, Chandler, AZ (US); Beomseok Choi, Chandler, AZ (US); Robert Sankman, Phoenix, AZ (US)

(73) Assignee: Intel Corporation, Santa Clara, CA (US)

(21) Appl. No.: 16/022,511

(22) Filed: Jun. 28, 2018

(51) Int. Cl. H01L 25/18; H01L 25/065; H02M 1/08

(52) U.S. Cl. CPC H01L 25/18; H01L 25/0652; H01L 25/0657; H02M 1/08; H01L 2225/0651; H01L 2225/06589; H01L 2225/06517; H01L 2225/06541; H01L 2225/06555; H01L 2225/06582; H01L 2225/06513

(57) ABSTRACT

A semiconductor package includes a first die and a second die. The first die includes a first plurality of compound semiconductor transistors, and where the first die includes a first section of a Power Management Circuitry (PMC). The second die includes a second plurality of transistors that are arranged as a plurality of CMOS (Complementary metal-oxide-semiconductor) circuitries, and where the second die includes a second section of the PMC. The PMC includes a power converter that includes: a plurality of power switches, a plurality of driver circuitries to correspondingly control the plurality of power switches, and a controller to control the driver circuitries. The first section of the PMC in the first die includes the plurality of power switches, and the second section of the PMC in the second die includes at least a part of the controller.

### BACKGROUND

In an integrated circuit package, a power management circuitry, which may include a power converter such as a voltage regulator (VR), may have power switches, and digital logic to control the power switches. It may be useful to efficiently use different technologies to implement different components of the power management circuitry.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 schematically illustrates a Power Management Circuitry (PMC) including a power converter and one or more other circuitries, where the PMC is partitioned into multiple sections such that individual sections are located in different locations of a semiconductor package, according to some embodiments.

FIG. 2 illustrates a cross sectional view of a semiconductor package, where a first die includes a first section of the PMC of FIG. 1, and where a second die includes a second section of the PMC of FIG. 1, according to some embodiments.

FIG. 3 illustrates a cross sectional view of a semiconductor package, where a compound semiconductor die includes a first section of the PMC of FIG. 1, and where two CMOS (Complementary metal-oxide-semiconductor) dies include a second section of the PMC of FIG. 1, according to some embodiments.

FIG. 4 illustrates a cross sectional view of a semiconductor package, where a compound semiconductor die includes a first section of the PMC of FIG. 1, where two CMOS dies include a second section of the PMC of FIG. 1, and where the two CMOS dies are at least in part within respectively two cavities of a substrate, according to some embodiments.

FIG. 5A illustrates a cross sectional view of a semiconductor package, where a compound semiconductor die includes a first section of the PMC of FIG. 1, where a CMOS die includes a second section of the PMC of FIG. 1, and where the compound semiconductor die is communicatively coupled to a substrate using a plurality of pillars that include conductive material, according to some embodiments.

FIG. 5B illustrates a cross sectional view of a semiconductor package, where a compound semiconductor die includes a first section of the PMC of FIG. 1, where a CMOS die includes a second section of the PMC of FIG. 1, and where the compound semiconductor die is communicatively coupled to a substrate using one or more interposers, according to some embodiments.

FIG. 6 illustrates a cross sectional view of a semiconductor package, where a compound semiconductor die includes a first section of the PMC of FIG. 1, where a CMOS die includes a second section of the PMC of FIG. 1, where the compound semiconductor die is on a first side of a substrate, and where the CMOS die is on a second side of the substrate, according to some embodiments.

FIG. 7 illustrates a cross sectional view of a semiconductor package, where a compound semiconductor die includes a first section of the PMC of FIG. 1, where a CMOS die includes a second section of the PMC of FIG. 1, where the compound semiconductor die is on a first side of a substrate, and where the CMOS die is at least in part embedded within the substrate, according to some embodiments.

FIG. 8 illustrates a cross sectional view of a semiconductor package, where a compound semiconductor die includes a first section of the PMC of FIG. 1, where a CMOS die includes a second section of the PMC of FIG. 1, and where the package is a wafer level chip-scale package (CSP), or another molded or reconstituted package, according to some embodiments.

FIG. 9 illustrates a flowchart depicting a method for operating a power converter, where sections of the power converter are split in a CMOS die and a compound semiconductor die, according to some embodiments.

FIG. 10 illustrates a computer system, a computing device or a SoC (System-on-Chip), where a PMC of the computing device is partitioned into at least a CMOS die and a compound semiconductor die, according to some embodiments.

### DETAILED DESCRIPTION

A Power Management Circuitry (PMC) may include various circuitries for managing power of a computing device. For example, the PMC may include a power converter, which may include multiple components, such as switches, drivers, controllers, feedback circuitries, and/or the like. In some embodiments, the components of a PMC are partitioned among multiple dies, instead of lumping all the components in a single die (e.g., to ensure flexible routing among the components of the PMC, to reduce routing distances between the components, to ensure that appropriate technology is used for individual components of the PMC, etc.).

For example, the PMC may include high-power switches of a power converter, and logic or digital circuitry to control the switches. In an example, the switches may be implemented using transistors that includes type III-V compound semiconductor material. The logic or digital portion of the PMC may be implemented using CMOS circuitries.

As will be discussed herein in further details, transistors that includes type III-V compound semiconductor material may be better suited for implementing the power switches of the power converter, while CMOS circuitries may be better suited for implementing the digital logic portion of the PMC. In some embodiments, in a semiconductor package, the PMC may be partitioned among a compound semiconductor die (e.g., a die that includes transistors comprising compound semiconductor material) and a CMOS die (e.g., a die that includes CMOS circuitries), where the power switches of the PMC may be included in the compound semiconductor die and the digital logic portion of the PMC may be included in the CMOS die. Various passive components of the power converter of the PMC may be on, or embedded within, a substrate of the semiconductor package.

In an example, partitioning the PMC into the compound semiconductor die and the CMOS die may result in flexible routing among the components of the PMC, reduce routing distances between the components of the PMC, ensuring that appropriate technology is used for individual components of the PMC, etc. Other technical effects will be evident from the various embodiments and figures.

One or more embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” or “some embodiments” means that a particular feature, structure, function, or characteristic described in connection with the embodiment is included in at least one embodiment of the invention. Thus, the appearances of the phrase “in an embodiment” or “in one embodiment” or “some embodiments” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship).

The terms “substantially,” “close,” “approximately,” “near,” and “about,” generally refer to being within +/−10% of a target value. For example, unless otherwise specified in the explicit context of their use, the terms “substantially equal,” “about equal” and “approximately equal” mean that there is no more than incidental variation between among things so described. In the art, such variation is typically no more than +/−10% of a predetermined target value.

The term “scaling” generally refers to converting a design (schematic and layout) from one process technology to another process technology and subsequently being reduced in layout area. The term “scaling” generally also refers to downsizing layout and devices within the same technology node. The term “scaling” may also refer to adjusting (e.g., slowing down or speeding up—i.e. scaling down, or scaling up respectively) of a signal frequency relative to another parameter, for example, power supply level.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

The terms “left,” “right,” “front,” “back,” “top,” “bottom,” “over,” “under,” and the like in the description and in the claims, if any, are used for descriptive purposes and not necessarily for describing permanent relative positions. For example, the terms “over,” “under,” “front side,” “back side,” “top,” “bottom,” “over,” “under,” and “on” as used herein refer to a relative position of one component, structure, or material with respect to other referenced components, structures or materials within a device, where such physical relationships are noteworthy. These terms are employed herein for descriptive purposes only and predominantly within the context of a device z-axis and therefore may be relative to an orientation of a device. Hence, a first material “over” a second material in the context of a figure provided herein may also be “under” the second material if the device is oriented upside-down relative to the context of the figure provided. In the context of materials, one material disposed over or under another may be directly in contact or may have one or more intervening materials. Moreover, one material disposed between two materials may be directly in contact with the two layers or may have one or more intervening layers. In contrast, a first material “on” a second material is in direct contact with that second material. Similar distinctions are to be made in the context of component assemblies.

The term “between” may be employed in the context of the z-axis, x-axis or y-axis of a device. A material that is between two other materials may be in contact with one or both of those materials, or it may be separated from both of the other two materials by one or more intervening materials. A material “between” two other materials may therefore be in contact with either of the other two materials, or it may be coupled to the other two materials through an intervening material. A device that is between two other devices may be directly connected to one or both of those devices, or it may be separated from both of the other two devices by one or more intervening devices.

Elements of the figures having the same reference numbers (or names) as the elements of any other figure can operate or function in any manner similar to that described, but are not limited to such.

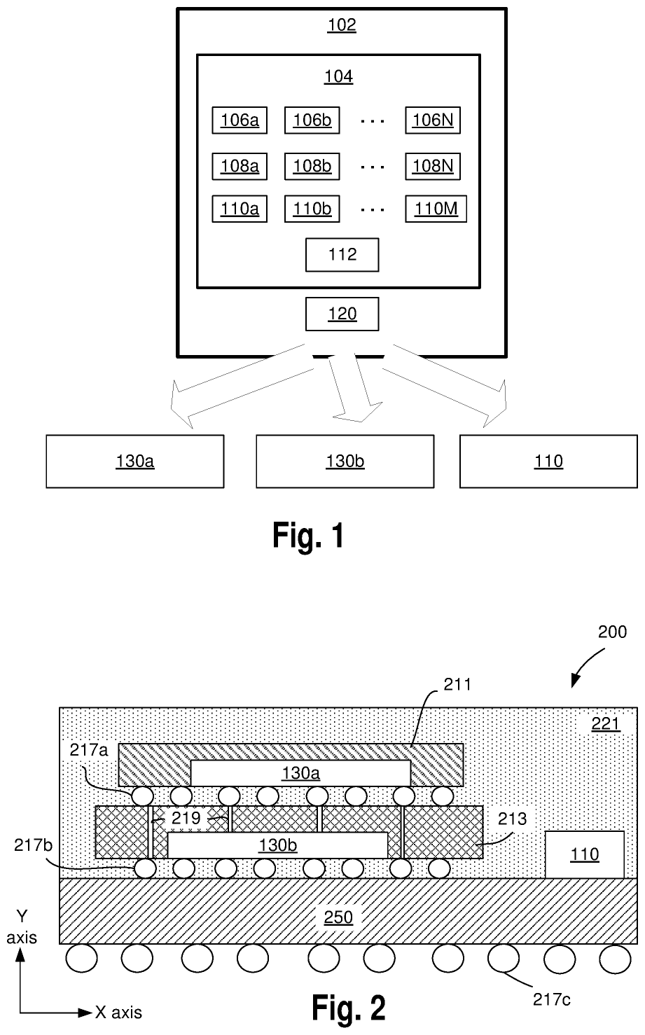

FIG. 1 schematically illustrates a Power Management Circuitry (PMC) 102 including a power converter 104 and one or more other circuitries 120, where the PMC 102 is partitioned into multiple sections such that individual sections are located in different locations of a semiconductor package, according to some embodiments. In some embodiments, the power converter 104 is a voltage regulator (VR), and is also referred to as VR 104. In some embodiments, the power converter 104 includes a plurality of power switches 106a, 106b, . . . , 106N, e.g., N number of switches, where N is an appropriate integer. The switches 106a, 106b, . . . , 106N may be implemented using any appropriate type of transistors, for example.

Elements referred to herein with a common reference label followed by a particular number or alphabet may be collectively referred to by the reference label alone. For example, switches 106a, 106b, . . . , 106N may be collectively and generally referred to as switches 106 in plural, and switch 106 in singular.

In an example, individual switch 106 may be controller by a corresponding driver circuitry 108. Driver circuitries 108a, 108b, . . . , 108N may respectively control the switches 106a, 106b, . . . , 106N. Merely as an example, a driver circuitry 108 may output a Pulse Width Modulation (PWM) signal to the corresponding switch 106, where a first value (e.g., one of a high value or low value) of the PWM signal may turn on the corresponding switch 106, and a second value (e.g., another of the high value or low value) of the PWM signal may turn off the corresponding switch 106.

In some embodiments, the power converter 104 also includes passive components 110a, 110b, . . . , 110M, e.g., M number of passive components, where M is an appropriate integer. Individual ones of the passive components 110 may be, for example, a capacitor, an inductor, etc.

In some embodiments, the power converter 104 also includes a control circuitry 112 that may control various aspects of operation of the power converter 104. For example, the control circuitry 112 may include digital logic and digital circuitry that may control the driver circuitries 108, to control the switching of the switches 110. In an example, the control circuitry 112 may receive a reference voltage (not illustrated in FIG. 1), and control the switching of the switches 106 such that a voltage output of the power converter 104 (not illustrated in FIG. 1) substantially tracks the reference voltage. The voltage output of the power converter 104 may be feedback to the control circuitry 112, to enable the control circuitry 112 to regulate the voltage output of the power converter 104.

The power converter 104 may include one or more other components (not illustrated in FIG. 1 for purposes of illustrative clarity). For example, the power converter 104 may include a plurality of sense circuitries to senses or measure voltage and/or current of individual switches 106 and/or individual drivers 110. The control circuitry 112 may receive such measurements, e.g., which may be used for soft switching of the power converter 104. Examples of soft switching, employing such sense circuitries, may be zero-voltage switching (ZVS), zero-current switching (ZCS), etc. ZVS or ZCS may enable the power converter 104 to engage in soft switching, avoiding possible switching losses that are typically incurred during PWM operation of the drivers 108.

The configuration of the switches 106, driver circuitries 108, passive components 110, the controller 112, etc. (e.g., a manner in which these components are arranged and interconnected) may be based on an implementation type of the power converter 104. For example, the power converter 104 may convert a Direct Current (DC) or Alternating Current (AC) voltage level to another DC or AC voltage level. Any appropriate type of VR may be used, e.g., a buck regulator, a boost regulator, a buck-boost regulator, a linear regulator, a low-dropout regulator, a switching regulator, and/or the like, and the type of power converter 104 does not limit the scope of this disclosure.

In some embodiments, the PMC 104 also includes one or more circuitries 120. The circuitries 120 may include one or more controllers to control the power converter 104, one or more digital I/O interface to communicate with other components of a computing system (e.g., to communicate about the voltage level of the power converter 104, to communicate about intended voltage levels of one or more other components of the computing system, etc.). In an example, the circuitries 120 may represent any circuitries that are typically present in a PMC, present in a Power Management Integrated Circuit (PMIC), a power management controller, etc. In an example, the circuitries 120 may include circuitries that may facilitate management of power (e.g., management of voltage, frequency, etc.) in the computing system. For example, the circuitries 120 may allocate power budgets to various components of the computing system, monitor power consumption of the various components of the computing system, dynamically update the power budgets, allocate operating voltage and/or frequency to the various components of the computing system, communicate with a battery circuitry to estimate remaining battery power, communicate with the power converter 104, and/or the like. The scope of this disclosure is not limited by the type of task performed by the circuitries 120, and the circuitries 120 may perform any appropriate power management tasks envisioned by those skilled in the art.

In some embodiments, various components of the PMC 102 are partitioned in sections 130a, 130b and passive components 110, where the sections 130a and 130b may be located in different regions of a semiconductor package. For example, the section 130a may be included in a first type of die, and the section 130b may be included in a second type of die, as discussed in further details herein.

FIG. 2 illustrates a cross sectional view of a semiconductor package 200, where a first die 211 includes a first section 130a of the PMC 102 of FIG. 1, and where a second die 213 includes a second section 130b of the PMC 102 of FIG. 1, according to some embodiments.

In some embodiments, the die 211 includes a plurality of transistors, where the transistors of the die 211 include compound semiconductor. A compound semiconductor is a semiconductor compound composed of elements of at least two different species. These semiconductors typically form in groups 13-15 (old groups III-V), for example of elements from group 13 (old group III, boron, aluminum, gallium, indium) and from group 15 (old group V, nitrogen, phosphorus, arsenic, antimony, bismuth). The range of possible formulae is broad, because these elements can form binary compound (e.g., two elements, such as Gallium Arsenide (GaAs)), ternary compound (e.g., three elements, such as indium gallium arsenide (InGaAs)), quaternary compound (e.g., four elements, such as Aluminum Gallium Indium Phosphide (AlInGaP)), etc. Examples of type III-V compound semiconductor materials include, but are not limited to, Gallium Nitride (GaN), Gallium arsenide (GaAs), Indium nitride (InN), Indium phosphide (InP), Indium arsenide (InAs), Silicon carbide (SiC), Indium gallium arsenide (InGaAs), Indium arsenide (InAs), etc. Thus, for example, the die 211 may be based on high bandgap technology, e.g., having transistors (e.g., field effect transistors) that use high bandgap compound semiconductor material. For example, the die 211 includes non-silicon FETs. Transistors employing type III-V compound semiconductor materials are also referred to herein as compound semiconductor transistors or compound semiconductor devices.

For purposes of this disclosure, a die including compound semiconductor transistors (e.g., the die 211) is also referred to as compound semiconductor die. Thus, the die 211 is also referred to as compound semiconductor die. The compound semiconductor die 211 primarily includes transistors with compound semiconductor, or includes transistors that are based on compound semiconductor.

In an example, the die 211 may not include CMOS (Complementary metal-oxide-semiconductor) circuitries. In another example, the die 211 may include relatively low number of transistors (e.g., relatively low number of Silicon based transistors) configured as CMOS circuitries, when compared to a number of compound semiconductor transistors.

In some embodiments, the die 213 includes a plurality of transistors, where the transistors of the die 213 include Silicon based transistors arranged as CMOS circuitries. For example, the CMOS circuitries of the die 213 may use complementary and/or symmetrical pairs of p-type and n-type metal oxide semiconductor field effect transistors (MOSFETs) to implement logic functions.

For purposes of this disclosure, a die including CMOS circuitries (e.g., the die 213) is also referred to as CMOS die. Thus, the die 213 is also referred to as CMOS die. The CMOS die 213 primarily includes Silicon transistors arranged as CMOS circuitries. The Silicon based transistors on the die 213, which are arranged as CMOS circuitries, are also referred to herein as Silicon transistors, Silicon devices, CMOS transistors or CMOS devices.

In an example, the die 213 may not include compound semiconductor transistors. In another example, the die 213 may include relatively low number of compound semiconductor transistors, when compared to a number of Silicon transistors arranged as CMOS circuitries.

Semiconductor processes using compound semiconductors (such as Gallium Nitride) may offer relatively better performance than conventional Silicon based CMOS circuitry for power conversion applications. Compound semiconductors offer high electron mobility, which allows switches constructed with compound semiconductors to be smaller than Silicon switches for a similar ON resistance, which may be a favorable characteristic for power switches. However, it may be relatively difficult to implement PMOS (P-type metal-oxide-semiconductor) devices using compound semiconductors, and hence, a compound semiconductors die may not be better suited to implement complex, low leakage digital logic. However, this may not necessarily be a problem for high-power switches of a power converter that may be designed with discrete components. Thus, in an example, a compound semiconductor die, such as the die 211, may be better suited for high power analog applications. In some embodiments, the compound semiconductor die, such as the die 211, may be used to implement the switches 106 of the power converter 104.

However, the logic to control the switches 106 (such as the control circuitry 112, the circuitries 120, etc.) may be difficult to be implemented in the compound semiconductor die 211. Thus, in some embodiments, digital logic circuitries of the PMC 102, such as the control circuitry 112, the circuitries 120, etc., may be implemented in the CMOS die 213.

Referring again to FIGS. 1 and 2, section 130a of the PMC 102 is implemented in the compound semiconductor die 211, and section 130b of the PMC 102 is implemented in the CMOS die 213. As discussed herein, the compound semiconductor die 211 may be better suited for analog circuitries, and hence, the switches 106a, . . . , 106N may be included in the section 130a that is implemented in the compound semiconductor die 211. The logic or digital part of the PMC 102 (e.g., the control circuitry 112, the circuitries 120, etc.) may be included in the section 130b that is implemented in the CMOS die 211.

In an example, the driver circuitries 108a, . . . , 108N may be included, along with the corresponding switches 106a, . . . , 108N, in the compound semiconductor die 211 (e.g., as it may be easier from routing and/or implementation perspective to implement the driver circuitries 108 in the compound semiconductor die 211). In another example, the driver circuitries 108a, . . . , 108N may be included (e.g., unlike the switches 106a, . . . , 108N) in the CMOS die 213. In yet another example, some sections of a driver circuitry 108 (e.g., sections that include analog components) may be included in the compound semiconductor die 211, while other sections of the driver circuitry 108 (e.g., sections that include digital logic) may be included in the CMOS die 213.

In an example, one or more analog components of the PMC 102 (e.g., the switches 106, analog sections of the driver circuitries 108, analog sections of the control circuitry 112, analog sections of the circuitries 120, etc.) may be included in the section 130a that is implemented in the compound semiconductor die 211. Also, one or more digital logic components of the PMC 102 (e.g., digital logic sections of the driver circuitries 108, digital logic sections of the control circuitry 112, digital logic sections of the circuitries 120, etc.) may be included in the section 130b that is implemented in the CMOS die 213.

Some examples of partitioning of the components of the PMC 102 between the section 130a (e.g., which is to be implemented in a compound semiconductor die) and the section 130b (e.g., which is to be implemented in a CMOS die) are discussed herein. However, the examples of the partitioning of the components of the PMC 102 between the sections 130a, 130b do not limit the scope of this disclosure, and the components of the PMC 102 may be partitioned between the sections 130a, 130b in any other appropriate manner. In an example, during such partitioning, analog components of the PMC 102 may primarily or mostly be included in the compound semiconductor die, and digital logic components of the PMC 102 may primarily or mostly be included in the CMOS die.

Referring again to FIG. 2, the dies 211 and 213 may be stacked over a substrate 250. A substrate discussed herein, such as the substrate 250, may be capable of providing electrical communications between an electrical component, such as an integrated circuit (IC) die, and a next-level component to which an IC package may be coupled (e.g., a circuit board). In an example, the substrate may comprise any suitable type of substrate capable of providing electrical communication between an IC die and an upper IC package coupled with a lower IC/die package, and in a further example a substrate may comprise any suitable type of substrate capable of providing electrical communication between an upper IC package and a next-level component to which an IC package is coupled. A substrate may also provide structural support for a die. By way of example, in one embodiment, a substrate may comprise a multi-layer substrate—including alternating layers of a dielectric material and metal built-up around a core layer (either a dielectric or a metal core). In another embodiment, a substrate may comprise a careless multi-layer substrate. Other types of substrates and substrate materials may also find use with the disclosed embodiments (e.g., ceramics, sapphire, glass, etc.). Further, according to one embodiment, a substrate may comprise alternating layers of dielectric material and metal that are built-up over a die itself—this process is sometimes referred to as a “bumpless build-up process.” Where such an approach is utilized, conductive interconnects may or may not be needed (as the build-up layers may be disposed directly over a die, in some cases).

In an example, the die 213 (e.g., an active side of the die 213) is coupled to the substrate 250 using a plurality of interconnect structures 217b, and the die 211 (e.g., an active side of the die 211) is coupled to the die 213 using a plurality of interconnect structures 217a. The substrate 250 may include a plurality of interconnect structures 217c for coupling the package 200 to an external component (e.g., a motherboard, a printed circuit board, etc.). The interconnect structures 217 (and various other interconnect structures discussed in this disclosure, unless mentioned otherwise), for example, are bumps, bump pads, metal pillars (e.g., copper pillars), balls formed using metals, alloys, solderable material, or the like. The interconnect structures 217 (and various other interconnect structures discussed in this disclosure, unless mentioned otherwise), for example, are solder formed using metals, alloys, solderable material, or the like.

The die 213 may include Through substrate Vias (TSVs) 219, which may communicatively couple (e.g., conductively coupled) the components within the section 130a to the components within the section 130b. The TSVs 219 may also communicatively couple (e.g., conductively coupled) the die 211 to the substrate 250.

In some embodiments, the passive components 110 are on, or embedded within, the substrate 250. Merely as an example, a passive component 110, which may be an inductor, may be on package traces that are on or within the substrate 250. In another example, the inductor may be air core inductor (ACI) on the substrate 250. In some other embodiments (and although not illustrated in FIG. 2), a passive component (e.g., an inductor) is included in one of the dies 211, 213. For example, the inductor may be a TSV inductor that is formed on a TSV of one of the dies 211, 213, e.g., a spiral inductor based on TSV technology. In another example, a passive component 110, which may be a capacitor (e.g., a thin film capacitor, a discrete capacitor, etc.), may be on or embedded within the substrate 250.

The dies 211, 213 may be encapsulated with an encapsulant or molding compound 221. In the example of FIG. 2, the molding compound 221 over-molds the die 211, such that a top surface of the die 211 is encapsulated by the molding compound 221. In another example (and although not illustrated in FIG. 2), the molding compound 221 may be flush or coplanar with the top surface of the die 211 (e.g., such that the top surface of the die 211 is exposed through the molding compound 221. In such an example, a heat sink may be optionally coupled to the top surface of the die 211. In an example, as the die 211 includes the power switches 206, the die 211 may generate more heat, which may be dissipated through the exposed top surface of the die 211 (or through the heat sink attached to the top surface of the die 211). In another example in which the die 211 is over-molded (e.g., as illustrated in FIG. 2), the heat generated in the die 211 may escape through the die 213 and the substrate 250.

In the package 200, a length of the path between the sections 130a and 130b is relatively short, e.g., may include the length of the TSVs 219 and the length of the interconnect structures 217a. Such a short routing distance between a component of the section 130a and a component of the section 130b may reduce or eliminate any parasitic inductance, and may have relatively low resistance.

In an example, a pitch of the interconnect structures 217a may be relatively coarse (e.g., larger than a pitch typically used in a die that includes a processor), which may simplify the assembly process and lower the cost. In an example, the pitch of the interconnect structures 217a may be relatively coarse because there may not be a large number of connections between the power switches 106 and remaining digital logic components of the PMC 102 (e.g., as compared to a die includes a processor or includes other complex logic components).

Although the section 130a is illustrated in FIG. 2 (and various subsequent figures) to be lumped in a compound semiconductor die and the section 130b is illustrated to be lumped in a CMOS die, such illustrations are merely symbolic and for illustrative purposes. For example, components of the PMC 102 within the section 130a may be at different locations within a compound semiconductor die, and components of the PMC 102 within the section 130b may be at different locations within a CMOS die.

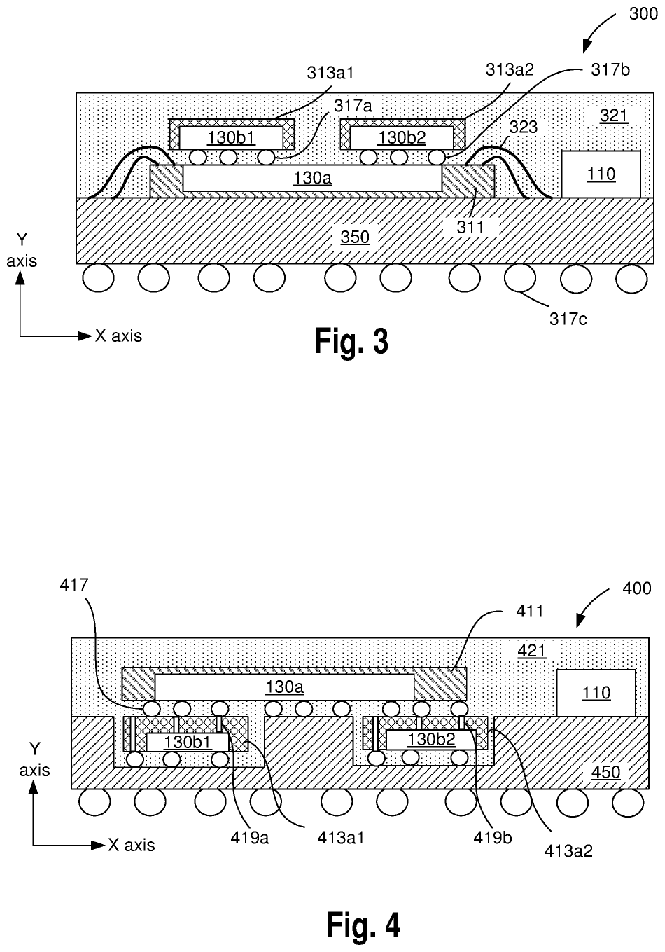

FIG. 3 illustrates a cross sectional view of a semiconductor package 300, where a compound semiconductor die 311 includes a first section 130a of the PMC 102 of FIG. 1, and where two CMOS dies 313a1, 313a2 include a second section 130b of the PMC 102 of FIG. 1, according to some embodiments.

The compound semiconductor die 311 may be at least in part similar to the compound semiconductor die 211 of FIG. 2. For example, the compound semiconductor die 311 may include transistors comprising compound semiconductor material. The compound semiconductor die 311 includes the section 130a of the PMC 102, similar to FIG. 2.

In the package 300, the section 130b of the PMC 102 is split in two sections 130b1 and 130b2. The CMOS die 313a1 includes the section 130b1, and the CMOS die 313a2 includes the section 130b2.

In some embodiments, the compound semiconductor die 311 is attached to the substrate 350 using an adhesive layer (not illustrated in FIG. 1), or using another appropriate arrangement. The die 311 may be in a flip-chip arrangement, with active surface of the die 311 on top. The die 311 may be wire-bonded, via wires 323, to the substrate 350.

The CMOS die 313a1 may be coupled to a section of the top surface of the compound semiconductor die 311 via interconnect structures 317a, and the CMOS die 313a2 may be coupled to another section of the top surface of the compound semiconductor die 311 via interconnect structures 317b.

In some embodiments, the passive components 110 are on, or embedded within, the substrate 350. Merely as an example, a passive component 110, which may be an inductor, may be on package traces that are on or within the substrate 350. In another example, the inductor may be air core inductor on the substrate 350. In some other embodiments (and although not illustrated in FIG. 3), a passive component (e.g., an inductor) is included in one of the dies 311, 313a, 313b. For example, the inductor may be a TSV inductor that is formed on a TSV of one of the dies 311, 313a, 313b, e.g., a spiral inductor based on TSV technology. In another example, a passive component 110, which may be a capacitor (e.g., a thin film capacitor, a discrete capacitor, etc.), may be on or embedded within the substrate 350. The dies 311, 313a, 313b may be encapsulated with an encapsulant or molding compound 321.

FIG. 4 illustrates a cross sectional view of a semiconductor package 400, where a compound semiconductor die 411 includes a first section 130a of the PMC 102 of FIG. 1, where two CMOS dies 413a1, 413a2 include a second section 130b of the PMC 102 of FIG. 1, and where the two CMOS dies 413a1, 413a2 are at least in part within respectively two cavities of a substrate 450, according to some embodiments.

The compound semiconductor die 411 may be at least in part similar to the compound semiconductor die 211 of FIG. 2. For example, the compound semiconductor die 411 may include transistors comprising compound semiconductor material. The compound semiconductor die 411 includes the section 130a of the PMC 102, similar to FIG. 2.

In the package 400, the section 130b of the PMC 102 is split in two sections 130b1 and 130b2 (e.g., similar to FIG. 3). The CMOS die 413a1 includes the section 130b1, and the CMOS die 413a2 includes the section 130b2.

In some embodiments, the substrate 450 has at least a first cavity, and a second cavity. The two CMOS dies 413a1, 413a2 are at least in part within the two cavities, respectively, of the substrate 450. The compound semiconductor die 411 is on the two CMOS dies 413a1, 413a2 and on an un-recessed section of the substrate 450. The section 130b1 is coupled to the section 130a via TSVs 419a within the die 413a1 and interconnect structures 417, and the section 130b2 is coupled to the section 130a via TSVs 419b within the die 413a2 and interconnect structures 417.

In some embodiments, the passive components 110 are on, or embedded within, the substrate 450, and/or on TSVs of one of the dies 411, 413a, 413b, e.g., as discussed with respect to FIG. 3. The dies 411, 413a1, 413a2 may be at least in part encapsulated by the molding compound 421. As discussed with respect to FIG. 2 (and although not illustrated in FIG. 3), a top surface of the die 411 may be exposed outside the molding compound 421, e.g., for heat dissipation. A heat sink may be coupled, in some examples, to the exposed top surface of the die 411.

Similar to FIG. 2, in the package 400, a length of the path between the section 130a and the sections 130b1, 130b2 are relatively short, e.g., may include the length of the TSVs 419 and the length of the interconnect structures 417 between the dies. Such a short routing distance between a component of the section 130a and a component of any of the sections 130b1, 130b2 may reduce or eliminate parasitic inductance, and may have relatively low resistance. In some embodiments, a pitch of the interconnect structures 417 may be relatively coarse (e.g., larger than a pitch typically used in a die that includes a processor), which may simplify the assembly process and lower the cost.

As the CMOS die(s) are to implement logic and the compound semiconductor die is to implement relatively larger high-power switches, in an example, the compound semiconductor die may have a larger area than the CMOS die(s). Splitting the CMOS die into two CMOS dies 413a1, 413a2 may allow the CMOS dies to be relatively small, e.g., taking up a fraction of the area of the compound semiconductor die 411. This may result in cost savings associated with the CMOS dies 413a1, 413a2.

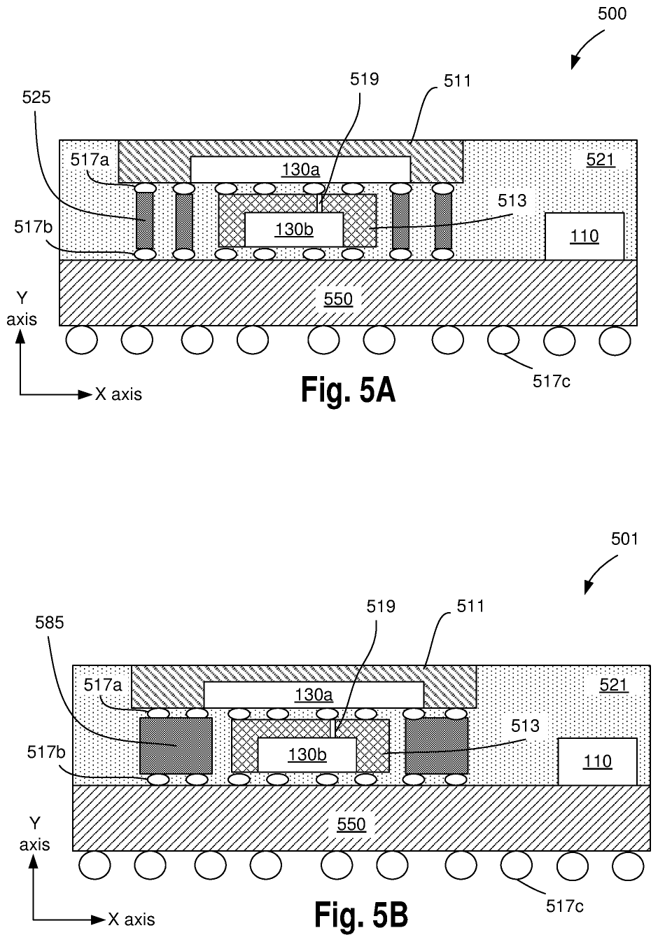

FIG. 5A illustrates a cross sectional view of a semiconductor package 500, where a compound semiconductor die 511 includes a first section 130a of the PMC 102 of FIG. 1, where a CMOS die 513 includes a second section 130b of the PMC 102 of FIG. 1, and where the compound semiconductor die 511 is communicatively coupled (e.g., conductively coupled) to a substrate 550 using a plurality of pillars 525 that include conductive material, according to some embodiments.

The compound semiconductor die 511 may be at least in part similar to the compound semiconductor die 211 of FIG. 2. For example, the compound semiconductor die 511 may include transistors including compound semiconductor material. The compound semiconductor die 511 includes the section 130a of the PMC 102, similar to FIG. 2.

The CMOS die 513 may be at least in part similar to the CMOS die 213 of FIG. 2. For example, the CMOS die 513 may include CMOS circuitries. The CMOS die 513 includes the section 130b of the PMC 102, similar to FIG. 2, and also includes TSVs 519.

As the CMOS die 513 is to implement logic components and the compound semiconductor die 511 is to implement relatively larger high-power switches, in an example, the compound semiconductor die 511 may have a larger area than the CMOS die 513, as illustrated in the example of FIG. 5A.

In some embodiments, the CMOS die 513 is coupled to the substrate 550 via interconnect structures 517b, and the compound semiconductor die 511 is stacked on the CMOS die 513 via interconnect structures 517a. The compound semiconductor die 511 may have a larger area than the CMOS die 513. Thus, sections of a bottom surface of the compound semiconductor die 511, which is not directly over the CMOS die 513, may be coupled directly to the substrate 550 (e.g., bypassing the CMOS die 513) using pillars 525. The pillars 525 are, for example, metal pillars, such as copper pillars. The pillars 525 couple at least some of the interconnect structures 517a, 517b, thereby providing direct path between the die 511 and the substrate 550.

In some embodiments, the passive components 110 are on, or embedded within, the substrate 550, and/or on TSVs of one of the dies 511, 513, e.g., as discussed with respect to FIG. 3. The dies 511, 513 may be at least in part encapsulated by the molding compound 521. In the example of FIG. 5A, a top surface of the die 511 may be exposed outside the molding compound 521, e.g., for heat dissipation. A heat sink may be coupled, in some examples, to the exposed top surface of the die 511. In another example, the molding compound 521 may encapsulate the top surface of the die 511.

The pillars 525, among other things, may facilitate connection between the power switches 106 in the section 130a within the die 511 and the passive components 110. As discussed herein previously, a pitch of the interconnect structures 517 and the pillars 525 may be relatively coarse (e.g., larger than a pitch typically used in a die that includes a processor), which may simplify the assembly process and lower the cost. Accordingly, the pillars 525 can have a relatively large diameter, which may keep the resistance of connection between the die 511 and the substrate 550 to a relatively low value.

FIG. 5B illustrates a cross sectional view of a semiconductor package 501, where a compound semiconductor die 511 includes a first section 130a of the PMC 102 of FIG. 1, where a CMOS die 513 includes a second section 130b of the PMC 102 of FIG. 1, and where the compound semiconductor die 511 is communicatively coupled (e.g., conductively coupled) to a substrate 550 using one or more interposers 585, according to some embodiments.

The semiconductor package 501 of FIG. 5B is at least in part similar to the semiconductor package 500 of FIG. 5A. For example, the package 501 includes the compound semiconductor die 511 having the section 130a, and the CMOS die 513 having the section 130b of the PMC 102. However, unlike the package 500 of FIG. 5A that includes the pillars 525, in the package 501 of FIG. 5B the pillars 525 are replaced by interposers 585.

The interposers 585 may include, silicon, glass, ceramic, and/or the like. The interposers 585 may include traces, re-distribution layers (RDL), routing structures, TSVs, etc., to route signals between the die 511 and the substrate 550.

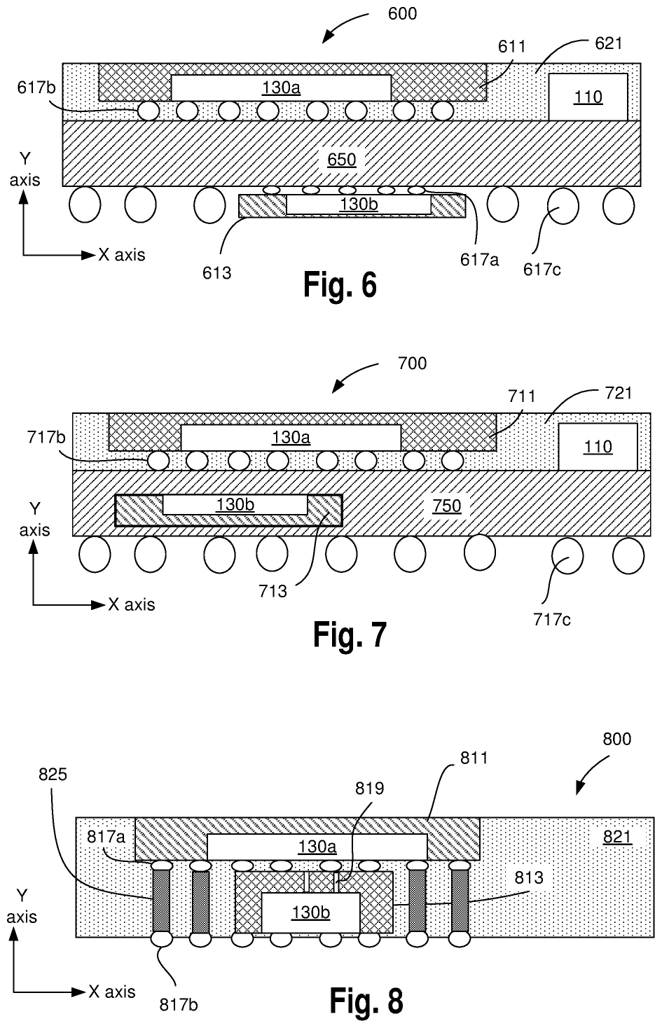

FIG. 6 illustrates a cross sectional view of a semiconductor package 600, where a compound semiconductor die 611 includes a first section 130a of the PMC 102 of FIG. 1, where a CMOS die 613 includes a second section 130b of the PMC 102 of FIG. 1, where the compound semiconductor die 611 is on a first side of a substrate 650, and where the CMOS die 613 is on a second side of the substrate 650, according to some embodiments.

The compound semiconductor die 611 may be at least in part similar to the compound semiconductor die 211 of FIG. 2. For example, the compound semiconductor die 611 may include transistors including compound semiconductor material. The compound semiconductor die 611 includes the section 130a of the PMC 102, similar to FIG. 2.

The CMOS die 613 may be at least in part similar to the CMOS die 213 of FIG. 2. For example, the CMOS die 613 may include CMOS circuitries. The CMOS die 613 includes the section 130b of the PMC 102, similar to FIG. 2.

In some embodiments, the compound semiconductor die 611 is on a first side (e.g., a top side) of the substrate 650, and the CMOS die 613 is on a second side (e.g., a bottom side) of the substrate 650. The compound semiconductor die 611 may be coupled to the substrate 650 via interconnect structures 617b, and the CMOS die 613 may be coupled to the substrate 650 via interconnect structures 617a. The substrate 650 may be coupled to interconnect structures 617c, which may be used to couple the package 600 to an external component (e.g., a motherboard, a printed circuit board, etc.). The substrate 650 may include routing structures, traces, RDLs, etc., to communicate signals between the dies 611 and 613.

In some embodiments, the passive components 110 are on, or embedded within, the substrate 650, and/or on TSVs of one of the dies 611, 613, e.g., as discussed with respect to FIG. 3. The die 611 may be at least in part encapsulated by the molding compound 621. In the example of FIG. 6, a top surface of the die 611 may be exposed outside the molding compound 621, e.g., for heat dissipation. A heat sink may be coupled, in some examples, to the exposed top surface of the die 611. In another example, the molding compound 621 may encapsulate the top surface of the die 611.

Thus, in FIG. 6, the CMOS die 613 may be on a landside surface of the substrate 650. Locating the CMOS die 613 on the bottom side of the substrate 650 may allow formation of the interconnect structures 617b to an entirety of a bottom surface of the compound semiconductor die 611, which may allow flexibility of distributing the interconnect structures 617b at appropriate locations on the bottom surface of the compound semiconductor die 611 (e.g., an interconnect structure 617b may be located close to a corresponding switch 106, to which the interconnect structure 617b is coupled).

FIG. 7 illustrates a cross sectional view of a semiconductor package 700, where a compound semiconductor die 711 includes a first section 130a of the PMC 102 of FIG. 1, where a CMOS die 713 includes a second section 130b of the PMC 102 of FIG. 1, where the compound semiconductor die 711 is on a first side of a substrate 650, and where the CMOS die 713 is at least in part embedded within the substrate 750, according to some embodiments.

The compound semiconductor die 711 may be at least in part similar to the compound semiconductor die 211 of FIG. 2. For example, the compound semiconductor die 711 may include transistors including compound semiconductor material. The compound semiconductor die 711 includes the section 130a of the PMC 102, similar to FIG. 2.

The CMOS die 713 may be at least in part similar to the CMOS die 213 of FIG. 2. For example, the CMOS die 713 may include CMOS circuitries. The CMOS die 713 includes the section 130b of the PMC 102, similar to FIG. 2.

In some embodiments, the compound semiconductor die 711 is on a first side (e.g., a top side) of the substrate 750, and the CMOS die 713 is embedded within the substrate 750. For example, the CMOS die 713 is embedded within the package substrate 750 using Molded Interconnect System Ball Grid Array (MISGA) technology, and/or other appropriate packaging technologies for embedding a die within a substrate.

The substrate 750 may be coupled to interconnect structures 717c, which may be used to couple the package 700 to an external component (e.g., a motherboard, a printed circuit board, etc.). The substrate 750 may include routing structures, traces, RDLs, etc., to communicate signals between the dies 711 and 713.

Embedding the CMOS die 713 within the substrate 750 may allow a full array of interconnect structures 717c (e.g., which may be BGA or Ball Grid Array balls) on the bottom of the package 700, which may not be possible in the package 600 of FIG. 6 (e.g., as the bottom of the package 600 is at least in part occupied by the CMOS die 613). Furthermore, a routing distance between the section 130a of the die 711 and the section 130b of the die 713 is relatively less (e.g., compared to the distance between the section 130a of the die 611 and the section 130b of the die 613 in the package 600 of FIG. 6), which may contribute to relatively less resistance and/or inductance between the sections 130a, 130b.

In some embodiments, the passive components 110 are on, or embedded within, the substrate 750, and/or on TSVs of one of the dies 711, 713, e.g., as discussed with respect to FIG. 3. The die 711 may be at least in part encapsulated by molding compound 721. In the example of FIG. 7, a top surface of the die 711 may be exposed outside the molding compound 721, e.g., for heat dissipation. A heat sink may be coupled, in some examples, to the exposed top surface of the die 711. In another example, the molding compound 721 may encapsulate the top surface of the die 711.

FIG. 8 illustrates a cross sectional view of a semiconductor package 800, where a compound semiconductor die 811 includes a first section 130a of the PMC 102 of FIG. 1, where a CMOS die 813 includes a second section 130b of the PMC 102 of FIG. 1, and where the package 800 is a wafer level chip-scale package (CSP), or another molded or reconstituted package, according to some embodiments.

The compound semiconductor die 811 may be at least in part similar to the compound semiconductor die 211 of FIG. 2. For example, the compound semiconductor die 811 may include transistors including compound semiconductor material. The compound semiconductor die 811 includes the section 130a of the PMC 102, similar to FIG. 2. The CMOS die 813 may be at least in part similar to the CMOS die 213 of FIG. 2, and may include TSVs 819. For example, the CMOS die 813 may include CMOS circuitries. The CMOS die 813 includes the section 130b of the PMC 102, similar to FIG. 2.

The package 800 is at least in part similar to the package 500 of FIG. 5A. For example, similar to the package 500, the package 800 of FIG. 8 includes pillars 825 (e.g., which may include conductive material, such as metal like copper, etc.) between interconnect structures 817a and 817b. However, unlike the package 500, the package 800 may not include a substrate (e.g., thereby lowering the cost). The package 800 is to be coupled to an external component (e.g., a motherboard, a printed circuit board, etc.) via the interconnect structures 817b. The pillars 825, among other things, may facilitate connection between the power switches 106 in the section 130a within the die 511 with the external component, via the package interconnect structures 817.

FIGS. 2-8 illustrate various example configurations in which a CMOS die and a compound semiconductor die may be arranged within a semiconductor package, where the CMOS die and the compound semiconductor die respectively include two sections of the PMC 102. Variations of these example configurations may be easily envisioned by those skilled in the art, based on the teachings of this disclosure. For example, in FIG. 2, the CMOS die 213 is on the substrate 250, and the compound semiconductor die 211 is on the CMOS die 213. In another example, the locations of the compound semiconductor die 211 and the CMOS die 213 may be interchanged (e.g., the compound semiconductor die 211 may be on the substrate 250, and the CMOS die 213 may be on the compound semiconductor die 211).

In another example, FIG. 3 illustrates partitioning or breaking up the CMOS die into two smaller CMOS dies 313a1 and 313a2. The teaching of partitioning or breaking up the CMOS die into two or more smaller CMOS dies may be applied to, for example, any of the packages of FIGS. 2, 5A, 5B, 6, 7, and/or 8.

In FIGS. 2-8, a CMOS die and a compound semiconductor die respectively include a first and a second section of the PMC 102. In some embodiments, in addition to including a corresponding section of the PMC 102, the CMOS die and/or the compound semiconductor die discussed herein may also include one or more logic or circuitries that are not functionality related to providing power management functionality.

Merely as an example, the CMOS die and/or the compound semiconductor die may include circuitry that may provide wireless connectivity (e.g., Bluetooth™ connectivity) to a computing device in which the corresponding package is included. For example, a wireless interface circuitry of the computing device may be powered on, even when one or more processors of the computing device are in a low power state. Locating the wireless interface circuitry on the same package as a power converter (e.g., the power converter 104) may ensure that the wireless interface circuitry receives power to stay on, e.g., even when one or more processors of the computing device are in the low power state.

In another example, CMOS die and/or the compound semiconductor die may include any appropriate circuitry that may receive power from the power converter 104, such as a processor, a memory, a cache, a Central Processing Unit (CPU), a Graphic Processing Unit (GPU), etc. In yet another example, a semiconductor package discussed herein (e.g., which includes a CMOS die and a compound semiconductor die) may include one or more additional dies (although not illustrated in any of the figures herein), where the one or more additional dies may include any appropriate circuitry that may receive power from the power converter 104, such as a processor, a memory, a cache, a CPU, a GPU, etc.

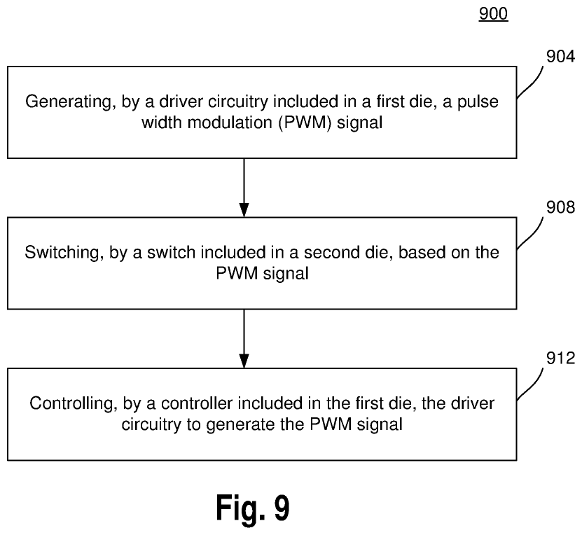

FIG. 9 illustrates a flowchart depicting a method 900 for operating a power converter (e.g., power converter 104, which may be a voltage regulator), where sections of the power converter are split in a CMOS die and a compound semiconductor die, according to some embodiments. Although the blocks in the flowchart with reference to FIG. 9 are shown in a particular order, the order of the actions can be modified. Thus, the illustrated embodiments can be performed in a different order, and some actions/blocks may be performed in parallel. Some of the blocks and/or operations listed in FIG. 9 may be optional in accordance with certain embodiments. The numbering of the blocks presented is for the sake of clarity and is not intended to prescribe an order of operations in which the various blocks must occur.

The method 900 includes, at 904, generating, by a driver circuitry (e.g., one of the driver circuitries 108a, . . . , 108N of FIG. 1) included in a first die, a PWM signal. In an example, the first die is a CMOS die and the driver circuitry is implemented at least in part using one or more CMOS circuitries.

At 908, a switch (e.g., one of the switches 106a, . . . , 106N of FIG. 1), which may be included in a second die, is switched ON and OFF, based at least in part on the PWM signal. The second die may be a compound semiconductor die, and the switch may include compound semiconductor material. In an example, the switching by the switch at least in part facilitates generation of an output voltage of the power converter.

At 912, a controller (e.g., controller 112 of FIG. 1), which may be included in any of the first die or the second die (e.g., the controller may be in the first die), controls the driver circuitry to generate the PWM signal. In an example, the controller is at least in part implemented using one or more CMOS circuitries.

In some embodiments, contrary to the illustrations of FIG. 9, the driver circuitry and the switch may be in a first die, and the controller may be at least in part in a second die.

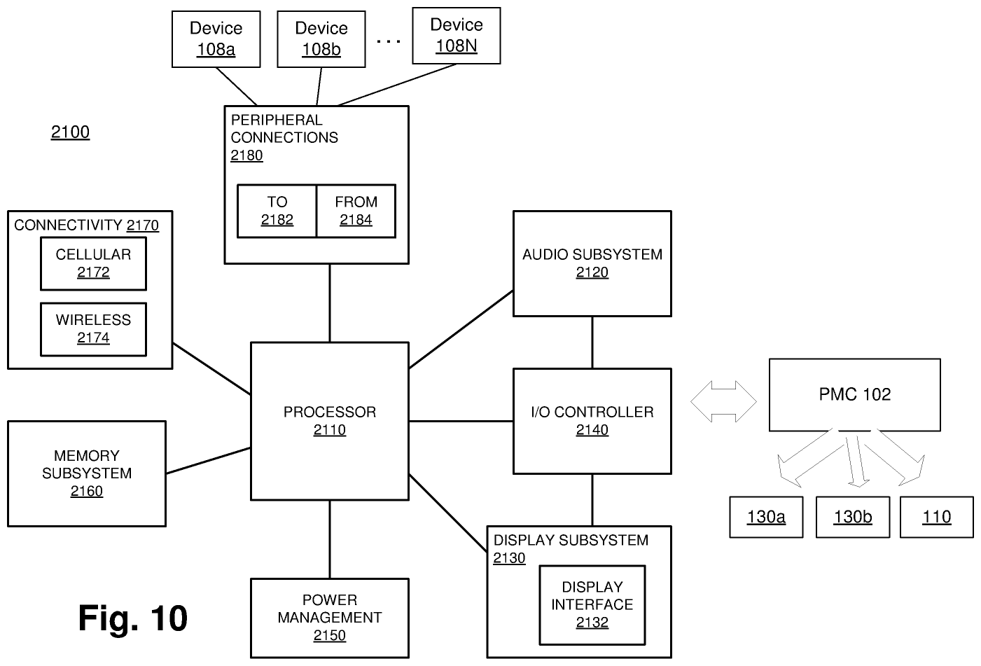

FIG. 10 illustrates a computer system, a computing device or a SoC (System-on-Chip) 2100, where a PMC (e.g., PMC 102) of the computing device is partitioned into at least a CMOS die and a compound semiconductor die, according to some embodiments. It is pointed out that those elements of FIG. 10 having the same reference numbers (or names) as the elements of any other figure can operate or function in any manner similar to that described, but are not limited to such.

In some embodiments, computing device 2100 represents an appropriate computing device, such as a computing tablet, a mobile phone or smart-phone, a laptop, a desktop, an IOT device, a server, a set-top box, a wireless-enabled e-reader, or the like. It will be understood that certain components are shown generally, and not all components of such a device are shown in computing device 2100.

In some embodiments, computing device 2100 includes a first processor 2110. The various embodiments of the present disclosure may also comprise a network interface within 2170 such as a wireless interface so that a system embodiment may be incorporated into a wireless device, for example, cell phone or personal digital assistant.

In one embodiment, processor 2110 can include one or more physical devices, such as microprocessors, application processors, microcontrollers, programmable logic devices, or other processing means. The processing operations performed by processor 2110 include the execution of an operating platform or operating system on which applications and/or device functions are executed. The processing operations include operations related to I/O with a human user or with other devices, operations related to power management, and/or operations related to connecting the computing device 2100 to another device. The processing operations may also include operations related to audio I/O and/or display I/O.

In one embodiment, computing device 2100 includes audio subsystem 2120, which represents hardware (e.g., audio hardware and audio circuits) and software (e.g., drivers, codecs) components associated with providing audio functions to the computing device. Audio functions can include speaker and/or headphone output, as well as microphone input. Devices for such functions can be integrated into computing device 2100, or connected to the computing device 2100. In one embodiment, a user interacts with the computing device 2100 by providing audio commands that are received and processed by processor 2110.

Display subsystem 2130 represents hardware (e.g., display devices) and software (e.g., drivers) components that provide a visual and/or tactile display for a user to interact with the computing device 2100. Display subsystem 2130 includes display interface 2132, which includes the particular screen or hardware device used to provide a display to a user. In one embodiment, display interface 2132 includes logic separate from processor 2110 to perform at least some processing related to the display. In one embodiment, display subsystem 2130 includes a touch screen (or touch pad) device that provides both output and input to a user.

I/O controller 2140 represents hardware devices and software components related to interaction with a user. I/O controller 2140 is operable to manage hardware that is part of audio subsystem 2120 and/or display subsystem 2130. Additionally, I/O controller 2140 illustrates a connection point for additional devices that connect to computing device 2100 through which a user might interact with the system. For example, devices that can be attached to the computing device 2100 might include microphone devices, speaker or stereo systems, video systems or other display devices, keyboard or keypad devices, or other I/O devices for use with specific applications such as card readers or other devices.

As mentioned above, I/O controller 2140 can interact with audio subsystem 2120 and/or display subsystem 2130. For example, input through a microphone or other audio device can provide input or commands for one or more applications or functions of the computing device 2100. Additionally, audio output can be provided instead of, or in addition to display output. In another example, if display subsystem 2130 includes a touch screen, the display device also acts as an input device, which can be at least partially managed by I/O controller 2140. There can also be additional buttons or switches on the computing device 2100 to provide I/O functions managed by I/O controller 2140.

In one embodiment, I/O controller 2140 manages devices such as accelerometers, cameras, light sensors or other environmental sensors, or other hardware that can be included in the computing device 2100. The input can be part of direct user interaction, as well as providing environmental input to the system to influence its operations (such as filtering for noise, adjusting displays for brightness detection, applying a flash for a camera, or other features).

In one embodiment, computing device 2100 includes power management 2150 that manages battery power usage, charging of the battery, and features related to power saving operation. Memory subsystem 2160 includes memory devices for storing information in computing device 2100. Memory can include nonvolatile (state does not change if power to the memory device is interrupted) and/or volatile (state is indeterminate if power to the memory device is interrupted) memory devices. Memory subsystem 2160 can store application data, user data, music, photos, documents, or other data, as well as system data (whether long-term or temporary) related to the execution of the applications and functions of the computing device 2100. In one embodiment, computing device 2100 includes a clock generation subsystem 2152 to generate a clock signal.

Elements of embodiments are also provided as a machine-readable medium (e.g., memory 2160) for storing the computer-executable instructions (e.g., instructions to implement any other processes discussed herein). The machine-readable medium (e.g., memory 2160) may include, but is not limited to, flash memory, optical disks, CD-ROMs, DVD ROMs, RAMs, EPROMs, EEPROMs, magnetic or optical cards, phase change memory (PCM), or other types of machine-readable media suitable for storing electronic or computer-executable instructions. For example, embodiments of the disclosure may be downloaded as a computer program (e.g., BIOS) which may be transferred from a remote computer (e.g., a server) to a requesting computer (e.g., a client) by way of data signals via a communication link (e.g., a modem or network connection).

Connectivity 2170 includes hardware devices (e.g., wireless and/or wired connectors and communication hardware) and software components (e.g., drivers, protocol stacks) to enable the computing device 2100 to communicate with external devices. The computing device 2100 could be separate devices, such as other computing devices, wireless access points or base stations, as well as peripherals such as headsets, printers, or other devices.

Connectivity 2170 can include multiple different types of connectivity. To generalize, the computing device 2100 is illustrated with cellular connectivity 2172 and wireless connectivity 2174. Cellular connectivity 2172 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, or other cellular service standards. Wireless connectivity (or wireless interface) 2174 refers to wireless connectivity that is not cellular, and can include personal area networks (such as Bluetooth, Near Field, etc.), local area networks (such as Wi-Fi), and/or wide area networks (such as WiMax), or other wireless communication.

Peripheral connections 2180 include hardware interfaces and connectors, as well as software components (e.g., drivers, protocol stacks) to make peripheral connections. It will be understood that the computing device 2100 could both be a peripheral device (“to” 2182) to other computing devices, as well as have peripheral devices (“from” 2184) connected to it. The computing device 2100 commonly has a “docking” connector to connect to other computing devices for purposes such as managing (e.g., downloading and/or uploading, changing, synchronizing) content on computing device 2100. Additionally, a docking connector can allow computing device 2100 to connect to certain peripherals that allow the computing device 2100 to control content output, for example, to audiovisual or other systems.

In addition to a proprietary docking connector or other proprietary connection hardware, the computing device 2100 can make peripheral connections 2180 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other types.

In some embodiments, the computing device 2100 includes the PMC 102 of FIG. 1. The PMC 102 may be partitioned in sections 130a, 130b, and the passive components 110, e.g., as discussed with respect to FIG. 1. The section 130a may be included in a compound semiconductor die, and section 130b may be included in a CMOS die, e.g., as discussed with respect to FIGS. 1-9. The PMC 102 may supply to and/or manage power of various components of the computing device 2100, such as a processor, a memory, a communication interface, and/or other components of the computing device 2100.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional element.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

The following examples pertain to further embodiments. Specifics in the examples may be used anywhere in one or more embodiments. All optional features of the apparatus described herein may also be implemented with respect to a method or process.

Example 1. A semiconductor package comprising: a first die comprising a first plurality of transistors, wherein an individual transistor of the first plurality of transistors comprises type III-V compound semiconductor material, and wherein the first die includes a first section of a Power Management Circuitry (PMC); and a second die comprising a second plurality of transistors that are arranged as a plurality of CMOS (Complementary metal-oxide-semiconductor) circuitries, and wherein the second die includes a second section of the PMC, wherein the PMC comprises a power converter that includes: a plurality of power switches, a plurality of driver circuitries to correspondingly control the plurality of power switches, and a controller to control the driver circuitries, wherein the first section of the PMC in the first die includes the plurality of power switches, and wherein the second section of the PMC in the second die includes at least a part of the controller.

Example 2. The semiconductor package of example 1 or any other example, wherein the type III-V compound semiconductor material comprises one or more of: Gallium (Ga), Nitrogen (N), Arsenic (As), Indium (In), or Phosphorus (P).

Example 3. The semiconductor package of example 1, wherein the first die does not include CMOS circuitries, and the second die does not include type III-V compound semiconductor material transistors.

Example 4. The semiconductor package of any of examples 1-3or any other example, wherein the second section of the PMC in the second die includes the plurality of driver circuitries.

Example 5. The semiconductor package of any of examples 1-3 or any other example, wherein the first section of the PMC in the first die includes the plurality of driver circuitries.

Example 6. The semiconductor package of any of examples 1-3 or any other example, comprising: a substrate, wherein at least one of the first or second dies is on the substrate, wherein the power converter comprises a plurality of passive components, and wherein one or more of the plurality of passive components are on, or embedded within, the substrate.

Example 7. The semiconductor package of any of examples 1-3 or any other example, comprising: a substrate, wherein the first die and the second die are stacked on the substrate.

Example 8. The semiconductor package of any of example 1 or any other example, comprising: a third die comprising a third plurality of transistors that are arranged as another plurality of CMOS circuitries, wherein the third die includes a third section of the PMC, and wherein the third section of the PMC in the third die includes at least another part of the controller.

Example 9. The semiconductor package of example 8 or any other example, comprising: a substrate, wherein the first die is on the substrate, and wherein the second die and the third die are stacked on the first die.

Example 10. The semiconductor package of example 9 or any other example, wherein: the first die is in a flip-chip configuration and wire-bonded to the substrate.

Example 11. The semiconductor package of example 8 or any other example, comprising: a substrate having at least a first cavity and a second cavity, wherein the second die is at least in part within the first cavity and on the substrate, wherein the third die is at least in part within the second cavity and on the substrate, and wherein the first die is stacked on the second and third dies.

Example 12. The semiconductor package of any of examples 1-3 or any other example, comprising: a substrate, wherein the second die is coupled to the substrate via a first plurality of interconnect structures, wherein a first section of a surface of the first die is coupled to the second die via a second plurality of interconnect structures, and wherein a second section of the surface of the first die is coupled to the substrate via a plurality of pillars comprising conductive material.

Example 13. The semiconductor package of any of examples 1-3 or any other example, comprising: a substrate; and an interposer, wherein the second die is coupled to the substrate via a first plurality of interconnect structures, wherein a first section of a surface of the first die is coupled to the second die via a second plurality of interconnect structures, and wherein a second section of the surface of the first die is coupled to the substrate via the interposer.

Example 14. The semiconductor package of any of examples 1-3 or any other example, comprising: a substrate, wherein the first die is coupled to a first side of the substrate via a first plurality of interconnect structures, wherein the second die is coupled to a first section of a second side of the substrate via a second plurality of interconnect structures, wherein a third plurality of interconnect structures is attached to a second section of the second side of the substrate, the third plurality of interconnect structures to couple the semiconductor package to an external component.

Example 15. The semiconductor package of any of examples 1-3 or any other example, comprising: a substrate, wherein the first die is coupled to a first side of the substrate via a first plurality of interconnect structures, wherein the second die is embedded within the substrate, wherein a second plurality of interconnect structures is attached to a second side of the substrate, the second plurality of interconnect structures to couple the semiconductor package to an external component.

Example 16. A system comprising: a memory to store instructions; a processor to execute the instructions; a wireless interface to enable the processor to communicate with another system; a first die comprising devices that include compound semiconductor material; and a second die comprising a plurality of CMOS (Complementary metal-oxide-semiconductor) circuitries, wherein a power converter is to supply power to one or more of the memory, the processor, or the wireless interface, wherein the first die includes a first section of the power converter, and wherein the second die includes a second section of the power converter.

Example 17. The system of example 16 or any other example, wherein the first section of the power converter included in the first die comprises one or more power switches of the power converter, and wherein the second section of the power converter included in the second die comprises one or more driver circuitries that are to respectively drive the one or more power switches.

Example 18. A method of operating a voltage regulator (VR), the method comprising: generating, by a driver circuitry included in a first die, a pulse width modulation (PWM) signal; and switching, by a switch included in a second die, based on the PWM signal, where the switching by the switch at least in part generates an output voltage of the VR, wherein the switch comprises compound semiconductor material, and the driver circuitry is implemented at least in part using one or more CMOS (Complementary metal-oxide-semiconductor) circuitries.

Example 19. The method of example 18 or any other example, further comprising: controlling, by a controller included in the first die, the driver circuitry to generate the PWM signal.

Example 20. The method of any of examples 18-19 or any other example, further comprising: transmitting the PWM signal from the driver circuitry to the switch through a through substrate via and an interconnect structure.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

We claim:

1. A semiconductor package comprising:
a first die comprising a first plurality of transistors, wherein an individual transistor of the first plurality of transistors comprises type III-V compound semiconductor material, and wherein the first die includes a first section of a Power Management Circuitry (PMC); and
a second die comprising a second plurality of transistors that are arranged as a plurality of CMOS (Complementary metal-oxide-semiconductor) circuitries, and wherein the second die includes a second section of the PMC,
wherein the PMC comprises a power converter that includes: a plurality of power switches, a plurality of driver circuitries to correspondingly control the plurality of power switches, and a controller to control the driver circuitries,
wherein the first section of the PMC in the first die includes the plurality of power switches, and
wherein the second section of the PMC in the second die includes at least a part of the controller.

2. The semiconductor package of claim 1, wherein the type III-V compound semiconductor material comprises one or more of: Gallium (Ga), Nitrogen (N), Arsenic (As), Indium (In), or Phosphorus (P).

3. The semiconductor package of claim 1, wherein the first die does not include CMOS circuitries, and the second die does not include type III-V compound semiconductor material transistors.

4. The semiconductor package of claim 1, wherein the second section of the PMC in the second die includes the plurality of driver circuitries.

5. The semiconductor package of claim 1, wherein the first section of the PMC in the first die includes the plurality of driver circuitries.

6. The semiconductor package of claim 1, comprising:
a substrate, wherein at least one of the first or second dies is on the substrate,
wherein the power converter comprises a plurality of passive components, and
wherein one or more of the plurality of passive components are on, or embedded within, the substrate.

7. The semiconductor package of claim 1, comprising:
a substrate, wherein the first die and the second die are stacked on the substrate.

8. The semiconductor package of claim 1, comprising:
a third die comprising a third plurality of transistors that are arranged as another plurality of CMOS circuitries,
wherein the third die includes a third section of the PMC, and
wherein the third section of the PMC in the third die includes at least another part of the controller.

9. The semiconductor package of claim 8, comprising:
a substrate,
wherein the first die is on the substrate, and
wherein the second die and the third die are stacked on the first die.

10. The semiconductor package of claim 9, wherein:
the first die is in a flip-chip configuration and wire-bonded to the substrate.

11. The semiconductor package of claim 8, comprising:
a substrate having at least a first cavity and a second cavity,
wherein the second die is at least in part within the first cavity and on the substrate,
wherein the third die is at least in part within the second cavity and on the substrate, and
wherein the first die is stacked on the second and third dies.

12. The semiconductor package of claim 1, comprising:
a substrate,
wherein the second die is coupled to the substrate via a first plurality of interconnect structures,
wherein a first section of a surface of the first die is coupled to the second die via a second plurality of interconnect structures, and
wherein a second section of the surface of the first die is coupled to the substrate via a plurality of pillars comprising conductive material.

13. The semiconductor package of claim 1, comprising:
a substrate; and
an interposer,
wherein the second die is coupled to the substrate via a first plurality of interconnect structures,
wherein a first section of a surface of the first die is coupled to the second die via a second plurality of interconnect structures, and
wherein a second section of the surface of the first die is coupled to the substrate via the interposer.

14. The semiconductor package of claim 1, comprising:
a substrate,
wherein the first die is coupled to a first side of the substrate via a first plurality of interconnect structures,
wherein the second die is coupled to a first section of a second side of the substrate via a second plurality of interconnect structures,
wherein a third plurality of interconnect structures is attached to a second section of the second side of the substrate, the third plurality of interconnect structures to couple the semiconductor package to an external component.

15. The semiconductor package of claim 1, comprising:
a substrate,
wherein the first die is coupled to a first side of the substrate via a first plurality of interconnect structures,
wherein the second die is embedded within the substrate,
wherein a second plurality of interconnect structures is attached to a second side of the substrate, the second plurality of interconnect structures to couple the semiconductor package to an external component.

16. A system comprising:
a memory to store instructions;
a processor to execute the instructions;
a wireless interface to enable the processor to communicate with another system;
a first die comprising devices that include compound semiconductor material; and
a second die comprising a plurality of CMOS (Complementary metal-oxide-semiconductor) circuitries,
wherein a power converter is to supply power to one or more of the memory, the processor, or the wireless interface,
wherein the first die includes a first section of the power converter, and
wherein the second die includes a second section of the power converter.

17. The system of claim 16, wherein the first section of the power converter included in the first die comprises one or more power switches of the power converter, and wherein the second section of the power converter included in the second die comprises one or more driver circuitries that are to respectively drive the one or more power switches.

18. A method of operating a voltage regulator (VR), the method comprising:
generating, by a driver circuitry included in a first die, a pulse width modulation (PWM) signal; and
switching, by a switch included in a second die, based on the PWM signal,
where the switching by the switch at least in part generates an output voltage of the VR,
wherein the switch comprises compound semiconductor material, and
the driver circuitry is implemented at least in part using one or more CMOS (Complementary metal-oxide-semiconductor) circuitries.

19. The method of claim 18, further comprising:
controlling, by a controller included in the first die, the driver circuitry to generate the PWM signal.

20. The method of claim 18, further comprising:
transmitting the PWM signal from the driver circuitry to the switch through a through substrate via and an interconnect structure.
